(19) United States
(12) Patent Application Publication
(10) Pub. No.: US 2026/0143993 A1
(43) Pub. Date: May 21, 2026

(54) WAFER CLEANING DEVICE AND WAFER CLEANING METHOD

(71) Applicant: Samsung Electronics Co., Ltd., Suwon-si (KR)

(72) Inventors: YOUNCHEOL JEONG, Suwon-si (KR); SANGHYUN LEE, Suwon-si (KR); KIHYUN PARK, Suwon-si (KR)

(21) Appl. No.: 19/248,992

(22) Filed: Jun. 25, 2025

(30) Foreign Application Priority Data
Nov. 18, 2024 (KR) 10-2024-0164536

(51) Int. Cl. H01L 21/67; C11D 7/32; H01L 21/02; H01L 21/683

(52) U.S. Cl. CPC H10P 72/0416; C11D 7/3263; C11D 7/3272; H10P 70/20; H10P 72/78

(57) ABSTRACT

A wafer cleaning device according to an embodiment includes a chamber configured to accommodate a cleaning solution including a thermo-responsive polymer, the chamber having a structure with open top, a head assembly configured to suction one surface of a wafer and move the wafer so that the other surface of the wafer comes into contact with the cleaning solution, and a temperature adjustment unit arranged in the chamber and configured to adjust a temperature of the cleaning solution.

### CROSS-REFERENCE TO RELATED APPLICATION

This application claims priority under 35 USC § 119 to and the benefit of Korean Patent Application No. 10-2024-0164536 filed in the Korean Intellectual Property Office on November 18, 2024, the entire contents of which are incorporated herein by reference.

### BACKGROUND OF THE INVENTION

### (a) Field of the Invention

The present disclosure relates to a wafer cleaning device and a wafer cleaning method.

### (b) Description of the Related Art

After a chemical mechanical planarization (CMP) process, a post-CMP cleaning process is performed to remove particles and/or organic residues on a wafer.

In the post-CMP cleaning process, a physical cleaning method using a cylindrical brush is widely used, and a chemical cleaning method using a chemical cleaning solution including DIW is also performed during this process.

However, the existing wafer cleaning methods have a problem in that some of contaminants attached to the wafer would adhere to and accumulated on the brush, leading to reverse contamination of the wafer. For example, the cleaning methods using brushes may have above mentioned cleaning limit, and the cleaning limit of the brush causes a problem in that small particles remain on the wafer without being removed.

Particles remaining on the wafer may cause defects in subsequent processes, resulting in significant yield loss.

### SUMMARY OF THE INVENTION

Embodiments of the present disclosure have been proposed to address the above issues and to provide a wafer cleaning device and a wafer cleaning method capable of increasing a removal rate of particles attached to a wafer without limitation on a size and type of particles by controlling a temperature of a cleaning solution including a thermo-responsive polymer to change the cleaning solution into a rubbery state, and then bringing a wafer into contact with the cleaning solution to remove particles on the wafer by an adhesive force of the cleaning solution.

A wafer cleaning device according to an embodiment includes a chamber configured to accommodate a cleaning solution including a thermo-responsive polymer, the chamber having a structure with open top, a head assembly configured to suction one surface of a wafer and move the wafer so that the other surface of the wafer comes into contact with the cleaning solution, and a temperature adjustment unit arranged in the chamber and configured to adjust a temperature of the cleaning solution.

A wafer cleaning device according to an embodiment includes a chamber configured to accommodate a cleaning solution including a thermo-responsive polymer, the chamber having a cylindrical structure with open top, a loading unit configured such that a wafer is seated on the loading unit, a suction head configured to suction one surface of the wafer, a connection portion connected to the suction head on one side of the connection portion to support the suction head, a support portion connected to the other side of the connection portion to support the connection portion, the support portion rotatable about a vertical axis along with the suction head and to be movable along the vertical axis, and a temperature adjustment unit configured to adjust a temperature of the cleaning solution.

A wafer cleaning method according to an embodiment includes adjusting a temperature of a cleaning solution accommodated in a chamber to a first temperature, suctioning one surface of a wafer seated on a loading unit and moving the wafer above the chamber, moving the wafer downward so that the other surface of the wafer comes into contact with the cleaning solution, and separating the other surface of the wafer from the cleaning solution, in which the first temperature is a phase change temperature of the cleaning solution, and the cleaning solution is present in a rubbery state at the first temperature.

According to embodiments, particles on a wafer can be removed using an adhesive force of a thermo-responsive polymer, increasing particle removal efficiency and thereby minimizing yield loss in subsequent processes.

### BRIEF DESCRIPTION OF THE DRAWINGS

FIGS. 1 to 3 are diagrams illustrating a wafer cleaning device according to an embodiment.

FIG. 4 is a diagram illustrating a head assembly of the wafer cleaning device according to an embodiment.

FIG. 5 is a diagram illustrating a wafer cleaning device according to another embodiment.

FIGS. 6 and 7 are diagrams illustrating a wafer cleaning method according to an embodiment.

### DETAILED DESCRIPTION OF THE EMBODIMENTS

In the following detailed description, embodiments of the present disclosure have been described, with reference to the drawings. The inventive concept can be variously implemented and is not limited to the following embodiments.

The drawings and description are to be regarded as illustrative in nature and not restrictive. Like reference numerals designate like elements throughout the specification.

In addition, the size and thickness of each configuration shown in the drawings are arbitrarily shown for understanding and ease of description, and the inventive concept is not limited thereto. In the drawings, the thicknesses of layers, films, panels, regions, etc., are exaggerated for clarity. In the drawings, for understanding and ease of description, the thicknesses of some layers and areas are exaggerated.

Throughout the specification, when a part is referred to as being "connected" to another part, this includes not only a case where they are "directly connected", but also a case where they are "indirectly connected" with another member interposed therebetween. For example, when an element is referred to as being "directly connected," "directly attached," "directly joined," or "directly coupled" to another element, or as “contacting” or “in contact with” another element (or using any form of the word “contact”), there are no intervening elements present at the point of contact. In addition, unless explicitly described to the contrary, the word “comprise”, and its variations such as “comprises” or “comprising”, will be understood to imply the inclusion of stated elements but not the exclusion of any other elements.

Further, it will be understood that when an element such as a layer, film, region, or substrate is referred to as being "on" another element, it can be directly on the other element or intervening elements may also be present. In contrast, when an element is referred to as being “directly on” another element, there are no intervening elements present. Further, when an element is "on" a reference portion, the element is located above or below the reference portion, and it does not necessarily mean that the element is located "above" or "on" in a direction opposite to gravity. For example, spatially relative terms, such as “beneath,” “below,” “lower,” “above,” “upper,” “top,” “bottom,” “front,” “rear,” and the like, may be used herein for ease of description to describe positional relationships, such as illustrated in the figures, for example. It will be understood that the spatially relative terms encompass different orientations of the device in addition to the orientation depicted in the figures.

Further, in the entire specification, when it is referred to as "in a plan view," the view illustrates a target part viewed from above, and when it is referred to as "on a cross-section", it means when the cross-section obtained by cutting a target part vertically is viewed from the side.

As a post-CMP cleaning process of the related art, the physical and chemical cleaning methods using a brush to clean a wafer have a problem of causing reverse contamination of the wafer.

There are various methods for removing particles using fluid injection other than brushes, but it is still difficult to remove small particles smaller than 30 nm due to cleaning limit of each device.

In the cleaning method of the related art using DIW and chemical cleaning solutions, secondary problems occur in metal CMP, such as W, Mo, and Ru, due to exposure of the metal to the chemical cleaning solutions.

Accordingly, there is a need for a technology to efficiently remove particles including small-sized particles present on the wafer while preventing problems caused by the exposure of the metal to the chemical cleaning solutions.

A wafer cleaning device 10 and a wafer cleaning method according to some embodiments of the present disclosure may improve the above issues.

Hereinafter, the wafer cleaning device 10 and the wafer cleaning method according to embodiments of the present disclosure will be described in more detail with reference to the drawings.

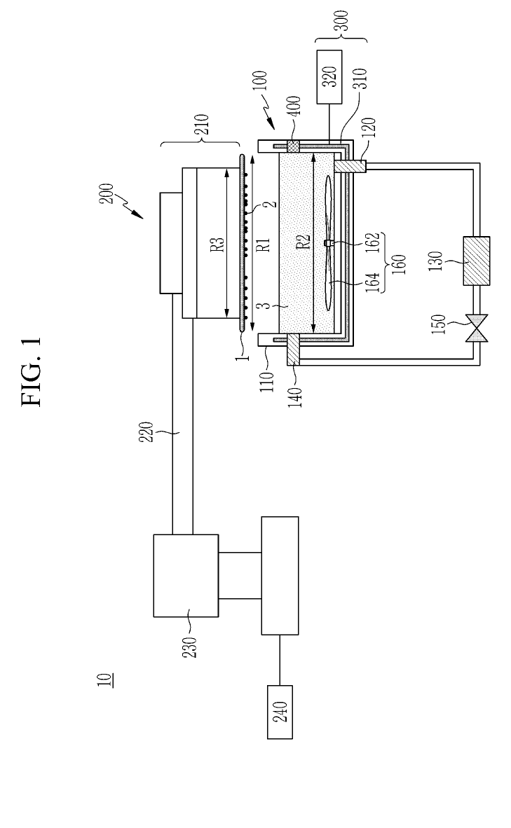

FIGS. 1 to 3 are diagrams illustrating a wafer cleaning device according to an embodiment.

FIGS. 1 to 3 are diagrams illustrating how the wafer cleaning device 10 according to an embodiment of the present disclosure cleans a wafer 1, sequentially showing a driving process of the wafer cleaning device 10.

First, referring to FIG. 1, the wafer cleaning device 10 may include a chamber 100 that accommodates a cleaning solution 3, a head assembly 200 that moves a wafer 1, and a temperature adjustment unit 300 that is arranged in the chamber 100 and adjusts a temperature of the cleaning solution 3.

The chamber 100 has a cylindrical structure/shape with open top and may include an accommodation unit 110 that accommodates the cleaning solution 3.

The head assembly 200 may serve to suction the wafer 1 (e.g., one surface of the wafer 1) and move the wafer 1 into the chamber 100 so that the other surface (e.g., an opposite surface) of the wafer 1 comes into contact with the cleaning solution 3.

A diameter R2 of an open region of the chamber 100, e.g., as viewed from one side of the chamber 100, may be equal to or greater than a diameter R1 of the wafer 1 and equal to or greater than a diameter R3 of a suction head 210.

The cleaning solution 3 may include a thermo-responsive polymer.

The thermo-responsive polymer is a polymer whose properties change depending on temperatures.

The thermo-responsive polymer may be a polymer that undergoes a reversible sol-gel phase transition or volume phase transition at a specific temperature. In the present disclosure, a temperature at which the sol-gel phase transition of the thermo-responsive polymer occurs is referred to as a phase change temperature.

In some embodiments, the cleaning solution 3 may include at least one of thermoplastic polyurethane (TPU) and poly(N-isopropylacrylamide) (PNIPAM).

However, the polymer included in the cleaning solution 3 is not limited to the polymers listed above, and may include another thermo-responsive polymer and/or an additional thermo-responsive polymer.

For example, the thermo-responsive polymer may include one or more polymers selected from the group consisting of poly(arylene ether sulfone), poly(N,N-diethylacrylamide), poly(N-ethylmethacrylamide), poly(methyl vinyl ether), poly(2-ethoxyethyl vinyl ether), poly(N-vinylcaprolactam), poly(N-vinylisobutyramide), and poly(N-vinyl-n-butyramide), or a copolymer thereof.

The cleaning solution 3 including the thermo-responsive polymer may be present in a rubbery state with an adhesive force at a first temperature. The first temperature may be the phase change temperature of the thermo-responsive polymer described above. For example, the first temperature may be the phase change temperature of the cleaning solution 3 including the thermo-responsive polymer.

As described above, the phase change temperature may be a temperature at which an amorphous solid changes from a solid state to a rubbery state.

Below the phase change temperature, the polymer remains in a hard, brittle glassy state, but above the phase change temperature, it becomes flexible like rubber.

At the phase change temperature, the cleaning solution 3 does not have fluidity like a fluid but becomes soft, unlike a glass phase, and this state may be called a rubbery state.

The phase change temperature may have different values depending on the type of polymer. Accordingly, a temperature range that can be the first temperature may vary depending on the type of thermo-responsive polymer. On average, the phase change temperature of a thermo-responsive polymer may fall within a range of 25°C to 30°C.

When the wafer 1 is brought into contact with the cleaning solution 3 at a point (first temperature) where the cleaning solution 3 is present in a rubbery state, particles 2 present on the wafer 1 may move to the cleaning solution 3 with an adhesive force. During this process, the particles 2 present on the wafer 1 may be removed from the wafer 1.

FIG. 1 is a diagram illustrating a state when the head assembly 200 of the wafer cleaning device 10 suctions a wafer 1 (e.g., suctions one surface of the wafer 1) and just before brings the other surface (an opposite surface) of the wafer 1 into contact with the cleaning solution 3 inside the chamber 100.

Before bringing the other surface of the wafer 1 into contact with the cleaning solution 3, the temperature of the cleaning solution 3 may be adjusted to the first temperature, which is the phase change temperature of the thermo-responsive polymer.

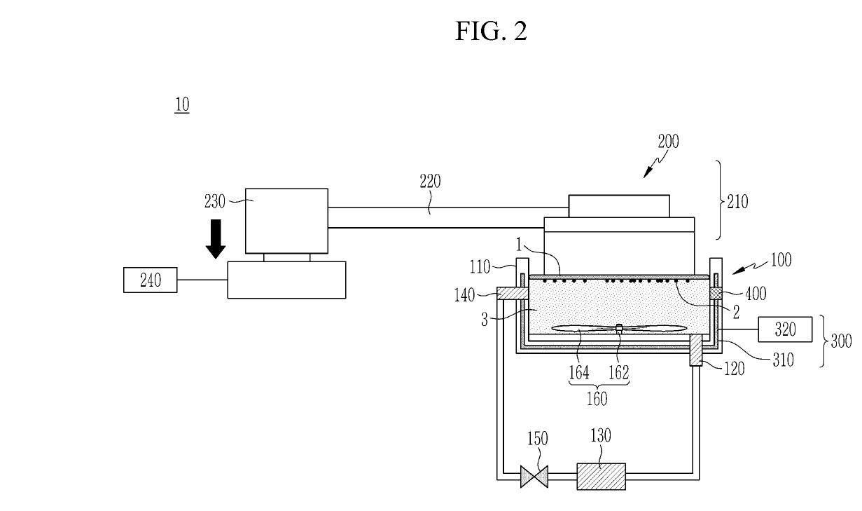

FIG. 2 is a diagram illustrating a state where the wafer 1 is in contact with the surface of the cleaning solution 3 at the first temperature.

During this process, the particles 2 present on the other surface (a lower surface) of the wafer 1 become attached to the surface of the cleaning solution 3, so that the particles 2 can be removed from the wafer 1. The cleaning solution 3 at the first temperature remains in the rubbery state and its surface is in a sticky state.

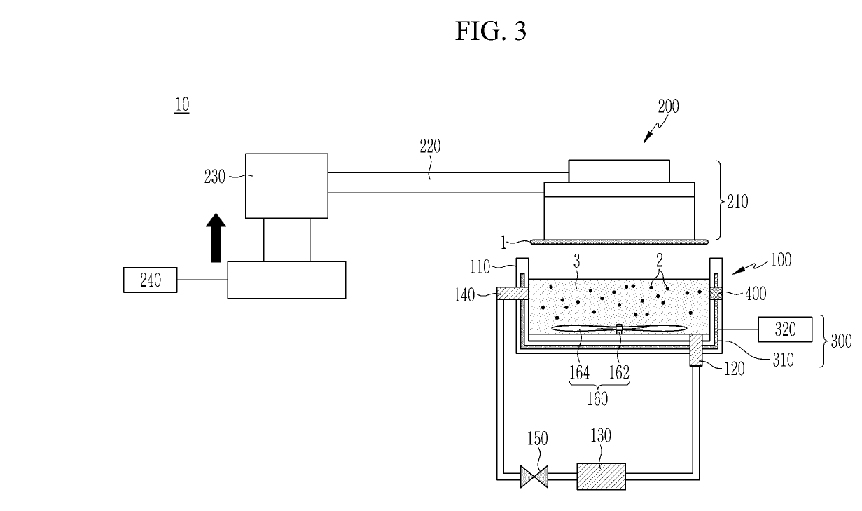

FIG. 3 is a diagram illustrating a state of separating the wafer 1, from which the particles 2 have been removed, from the cleaning solution 3.

As shown in FIG. 3, after the wafer 1 is separated from the cleaning solution 3, the temperature adjustment unit 300 may adjust the temperature of the cleaning solution 3 to a second temperature.

The cleaning solution 3 including the thermo-responsive polymer according to an embodiment of the present disclosure may be present in a liquid state at the second temperature.

Here, the second temperature may be a temperature equal to or higher than a melting point (Tm) of the cleaning solution 3.

The melting point may have different values depending on the type of polymer, and a temperature range of the second temperature may vary depending on the type of thermo-responsive polymer.

As shown in FIG. 3, by adjusting the temperature of the cleaning solution 3 including the particles 2 to the second temperature, the particles 2 may move freely in the cleaning solution 3 in a liquid state.

The chamber 100 may further include a rotating unit 160 that generates a vortex/swirl in the cleaning solution 3 accommodated in the accommodation unit 110. The rotating unit 160 serves to generate a vortex/swirl in the cleaning solution 3 in a liquid state. For example, the rotating unit 160 may be a stirrer.

The cleaning solution 3 at the first temperature, as shown in FIGS. 1 and 2, is in a state before becoming a liquid state, e.g., in a rubbery state, and in this state, there is no need to generate a vortex/swirl in the cleaning solution 3 at the first temperature. For example, the rotating unit 160 may not generate vortex/swirl in the cleaning solution 3 at the first temperature.

However, the cleaning solution 3 at a temperature equal to or higher than the second temperature, as shown in FIG. 3, is in a liquid state, and in this state, the rotating unit 160 may rotate to generate a vortex/swirl so that the cleaning solution 3 may rotate within the accommodation unit 110. This is to evenly disperse the particles 2 in the cleaning solution 3.

The rotating unit 160 may have a structure comprised of a shaft 162 and a plurality of wing portions 164 connected to the shaft 162.

As the shaft 162 rotates about an axis extending parallel to a longitudinal direction of the shaft 162, the plurality of wing portions 164 rotate in the cleaning solution 3, and during this process, a vortex/swirl may be generated in the cleaning solution 3.

According to an embodiment, in the case of FIG. 2 described above, when the cleaning solution 3 has a strong adhesive force, it may not be easy to separate the wafer 1 from the cleaning solution 3. Accordingly, as shown in FIG. 3, prior to separating the wafer 1, it is preferable to adjust the temperature of the cleaning solution 3 to a temperature slightly higher than the first temperature.

As the temperature of the cleaning solution 3 rises from the phase change temperature, the state changes from a rubbery state to a liquid state. As the state approaches a liquid state, the adhesive force also weakens.

The reason for raising the temperature of the cleaning solution 3 by only a certain temperature from the first temperature is to weaken the adhesive force of the cleaning solution 3, making it easier to separate the wafer 1 from the cleaning solution 3.

In addition, when the temperature of the cleaning solution 3 is raised by a certain temperature from the first temperature, as the cleaning solution 3 approaches a liquid phase, an effect is also achieved in which the particles 2 adhered to the surface of the cleaning solution 3 move into the cleaning solution 3. For example, the particles 2 positioned between the wafer 1 and the cleaning solution 3 can be separated from the wafer 1 in a greater distance. In the state shown in FIG. 2, by separating the particles 2 from the wafer 1 in a greater distance, the particles 2, which move along with the wafer 1 while attached to the wafer 1, can be minimized.

Assuming that the phase change temperature (first temperature) of the thermo-responsive polymer falls within the range of 25°C to 30°C on average, it is preferable to adjust the temperature of the cleaning solution to 40°C, which is a temperature slightly above the range of the phase change temperature, thereby lowering the adhesive force of the cleaning solution 3 and changing the cleaning solution toward a liquid state.

When using the cleaning solution 3 that is a thermo-responsive polymer, a cleaning process may avoid using DIW and chemical cleaning solutions used in the cleaning methods of the related art. Accordingly, even in processes where metal is exposed, such as an MOL (metal on layer) process (a process of making a metal-semiconductor bond and a contact plug thereon in an element), cleaning may avoid the problems caused by chemical cleaning solutions of the related art, which is an advantage over the methods of the related art.

In addition, since small-sized particles 2 that could not be removed due to the cleaning limit of brushes or the like are attached to the cleaning solution 3 by the adhesive force of the cleaning solution 3, an effect of increasing a removal rate of the particles 2 is also achieved.

The temperature adjustment unit 300 according to an embodiment of the present disclosure may include a heating portion 310 that is arranged in the chamber 100 accommodating the cleaning solution 3 and transfers heat to the cleaning solution 3, and a control unit 320 that controls a temperature of the heating portion 310. For example, the control unit 320 may be a temperature controller configured to control a temperature of the heating portion 310 in relation to the temperature of the cleaning solution 3. For example, the temperature controller may control energy provided to the heating portion 310. For example, the temperature controller may control electric power or a flow rate of a fluid provided to the heating portion 310. As an example, the temperature controller may be a thermostat.

The heating portion 310 may be arranged in the accommodation unit 110 of the chamber 100 in which the cleaning solution 3 is accommodated.

FIGS. 1 to 3 illustrate a state where the heating portion 310 is arranged inside a wall forming the bowl-shaped accommodation unit 110.

However, the structure of the heating portion 310 is not limited to the embodiments shown in FIGS. 1 to 3. The heating portion 310 may be structured in a way that allows it to directly or indirectly transfer heat to the cleaning solution 3 while arranged in the accommodation unit 110.

The heating portion 310 may be a coil. In this case, the heat of the heated coil can be transferred to the cleaning solution 3 to change the temperature of the cleaning solution 3.

In some embodiments, the heating portion 310 may be a hose, a pipe, or the like through which water or another fluid moves. In this case, by supplying hot water/fluid to the heating portion 310, the heat of the hot water/fluid can be transferred to the cleaning solution 3. For example, the fluid may be a liquid or a gas.

The wafer cleaning device 10 may further include a temperature sensor 400 that is arranged in the chamber 100 and detects the temperature of the cleaning solution 3.

In FIGS. 1 to 3, the temperature sensor 400 is shown as having a structure penetrating through the chamber 100.

However, the structure and arrangement location of the temperature sensor 400 are not limited to the embodiments shown in FIGS. 1 to 3. The temperature sensor 400 can be configured and positioned in any way without any limitations as long as it can detect the temperature of the cleaning solution 3.

In addition, the wafer cleaning device 10 may include a discharge portion 120 provided to the chamber 100 to discharge the cleaning solution 3 from the chamber 100, a filtering unit 130 to receive and filter the cleaning solution 3 discharged from the discharge portion 120, and an inlet portion 140 provided to the chamber 100 to introduce the cleaning solution 3 that has passed through the filtering unit 130 into the chamber 100. For example, the filtering unit 130 may be a filter configured to pass the cleaning solution 3 and retain solid particles. For example, the filtering unit 130 may be a solution filter or a liquid filter.

Additionally, the wafer cleaning device 10 may further include a pump 150 that applies pressure to the cleaning solution 3 so that the cleaning solution 3 having passed through the filtering unit 130 flows into the chamber 100.

The cleaning solution 3 that has completed cleaning of the wafer 1 can be maintained in a liquid state at the second temperature, as described with reference to FIG. 3.

The cleaning solution 3 in a liquid state can be discharged from the chamber 100 through the discharge portion 120. It is preferable that the rotating unit 160 rotates to generate a vortex/swirl in the cleaning solution 3 before discharging the cleaning solution 3. This is to prevent the particles 2 from remaining in the accommodation unit 110.

The filtering unit 130 can serve to filter the cleaning solution 3 containing the particles 2.

The filtering unit 130 serves to remove particles 2 contained in the cleaning solution 3, and the cleaning solution 3 that has passed through the filtering unit 130 may not contain the particles 2. Accordingly, the cleaning solution 3 according to an embodiment of the present disclosure can be reused.

The wafer cleaning device 10 according to an embodiment of the present disclosure has a feature of being able to repeatedly use the cleaning solution 3 by moving the particles 2 into the cleaning solution 3 using the adhesive force of the cleaning solution 3 in a rubbery state, and filtering the cleaning solution 3 in a liquid state to remove the particles 2 from the cleaning solution 3.

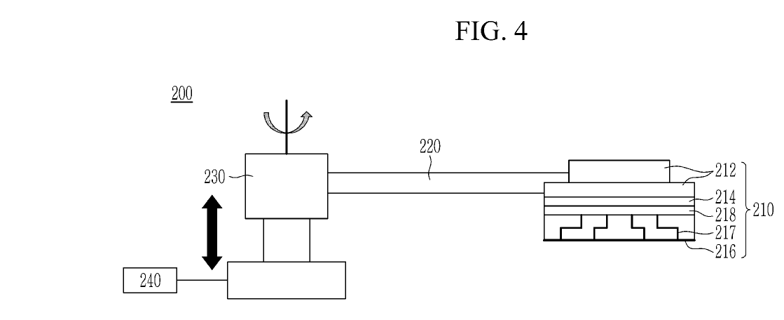

FIG. 4 illustrates a head assembly of the wafer cleaning device according to an embodiment.

As shown in FIG. 4, the head assembly 200 may include a suction head 210 having a bottom surface that is arranged horizontally to contact with one surface of the wafer 1 to suction the wafer 1, a connection portion 220 connected to the suction head 210 on one side/end of the connection portion 220 to support the suction head 210, a support portion 230 arranged with and/or spaced apart from the suction head 210 in a horizontal direction and connected to the other side/end of the connection portion 220 to support the connection portion 220, and a driving unit 240 that moves the support portion 230.

The support portion 230 can move vertically along with the suction head 210, and the movement direction of the support portion 230 may be referenced to the movement process of the support portion 230 in FIGS. 1 to 3.

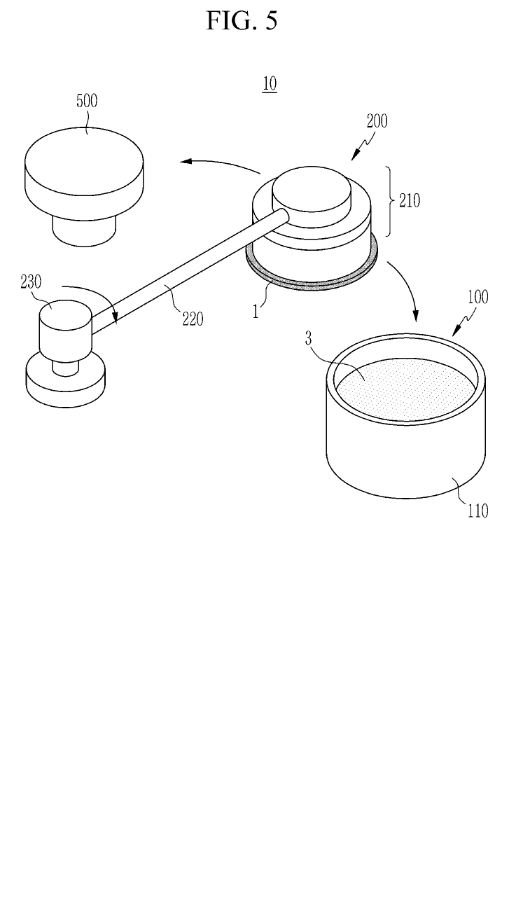

The support portion 230 can rotate about a vertical axis together with the suction head 210, and this can be referenced to the rotation process of the support portion 230 shown in FIG. 4 and FIG. 5 to be described below.

The driving unit 240 connected to the support portion 230 can vertically move the support portion 230, thereby enabling the suction head 210 suctioning the wafer 1 to move up and down.

The driving unit 240 can rotate the support portion 230 about an axis in a longitudinal/vertical direction to move the wafer 1, which has been cleaned in the chamber 100, to another location or to move the contaminated wafer 1 closer to and/or above the chamber 100 in order to clean the wafer 1.

In the wafer cleaning device 10 according to an embodiment of the present disclosure, the suction head 210 may include a support plate 212, a connection plate 214, and a suction plate 216.

The support plate 212 may have a structure in which one side is connected to and/or contact the connection portion 220. The connection plate 214 can be arranged on a lower surface of the support plate 212. For example, the support plate 212 can serve to connect and support the connection portion 220 and the suction head 210 (connection plate 214).

The suction plate 216 can be arranged on a lower surface of the connection plate 214. The connection plate 214 serves to connect the support plate 212 and the suction plate 216 and may have a structure made of silicon. For example, the connection plate 214 may be made of silicon or may include a portion made of silicon.

The suction plate 216 may have a structure in which an upper surface is in contact with the connection plate 214 and a lower surface is in contact with the wafer 1, e.g., while cleaning the wafer 1. The suction plate 216 can support the wafer 1 by suction force that suctions the wafer 1.

The suction plate 216 may have a structure made of silicon. For example, the suction plate 216 may be made of silicon or may include a portion made of silicon.

Both the connection plate 214 and the suction plate 216 may have structures made of silicon. The connection plate 214 may be helpful to minimize pressure for suctioning the wafer 1 and to control the pressure applied to the wafer 1 during the suction process of the wafer 1.

When the part supporting the wafer 1 is made of silicon, the suction plate 216 can have a uniform density throughout and high compressibility and/or may apply a uniform pressure to the wafer 1.

Silicon is a material that minimizes air leakage and has an advantage of being able to firmly attach the wafer 1 to the suction head 210 while suctioning the wafer at low pressure.

The suction plate 216 made of silicon may be provided with a boundary 217, as shown in FIG. 4. For example, the silicon structure forming the suction plate 216 may be comprised of multiple pieces. For example, the suction plate 216 may have a structure in which separated blocks of silicon are attached to each other with the boundary 217 therebetween. Accordingly, it is possible to provide the wafer 1 with uniform suction force and to prevent the wafer 1 from slipping or breaking.

As shown in FIG. 4, a vacuum portion 218 may be placed between the suction plate 216 and the connection plate 214. The vacuum portion 218 may be a chamber whose interior is under vacuum or capable of vacuum.

In FIG. 4, the vacuum portion 218 is shown as a separate layer from the connection plate 214 and the suction plate 216, but the vacuum portion 218 may also be structured to be arranged inside the connection plate 214. For example, the vacuum portion 218 may be integrated with the connection plate 214 or with the suction plate 216 in certain embodiments.

Although not shown, a vacuum line may be provided inside the suction plate 216. One side/end of the vacuum line may be arranged open in a direction in which the wafer 1 is attached, e.g., at a bottom surface of the suction plate 216, and the other side/end of the vacuum line may be structured to be open toward the vacuum portion 218, e.g., on an inner wall of the vacuum portion 218.

A suction force (drawing force) may be generated in a direction from the one side/end toward the other side/end of the vacuum line. The wafer 1 can be suctioned to the suction head 210 (suction plate 216) by the suction force generated through the vacuum line.

Although the vacuum portion 218 is shown as a single communicating structure in the drawing, no such limitation is intended. For example, multiple vacuum lines may pass through the suction plate 216, and multiple vacuum portions 218 formed of separated rooms may be connected to the multiple vacuum lines, respectively. For example, at each location where suction force is generated by a corresponding vacuum line, a corresponding one of the multiple vacuum portions 218 may be arranged/connected in the form of a corresponding one of the separated rooms.

In addition, although not shown in the drawing, each vacuum portion 218 may further include a suction pump that generates a suction force. The location where the suction pump is arranged is not limited. Additionally, a suction hole connecting the vacuum portion 218 and the suction pump may be further included.

FIG. 5 is a diagram illustrating a wafer cleaning device according to another embodiment.

In FIG. 5, the structures of the chamber 100 and the head assembly 200 are simply shown, and some configurations of the temperature adjustment unit 300 and other components are omitted, but it is assumed that each omitted structure is the same as the corresponding structure shown in FIGS. 1 and 4 unless contexts indicate otherwise.

Referring to FIGS. 1, 4, and 5, a wafer cleaning device 10 according to an embodiment of the present disclosure may include a chamber 100 that accommodates a cleaning solution 3 and has a cylindrical structure with open top, a loading unit 500 that is arranged close to or horizontally spaced apart from the chamber 100 for a wafer 1 being seated on the loading unit, a suction head 210 that is arranged to hold the wafer 1 and suctions one surface of the wafer 1, a connection portion 220 that is connected to the suction head 210 on one side/end of the connection portion 220 to support the suction head 210, a support portion 230 that is connected to the other side/end of the connection portion 220 to support the connection portion 220 and can rotate about an axis in a direction perpendicular together with the suction head 210 and vertically move along the axis, and a temperature adjustment unit 300 that adjusts a temperature of the cleaning solution 3. The cleaning solution 3 may include a thermo-responsive polymer.

A diameter R2 of an open region of the chamber 100, e.g., as viewed from one side of the chamber 100 or in a plan view, may be equal to or greater than a diameter R1 of the wafer 1 (see FIGS. 1 and 4). As such, an entire area of the other surface of the wafer 1 can move through the open area within the chamber 100 while facing downward and come into contact with a top surface of the cleaning solution 3 while maintaining facing downward.

Additionally, the diameter R2 of the open area of the chamber 100 may be equal to or greater than a diameter R3 of the suction plate 216 of the suction head 210 (see FIGS. 1 and 4). As such, even the suction plate 216 of the suction head 210 that suctions the wafer 1 can move into the accommodation unit 110 together with the wafer 1 while maintaining a bottom surface of the suction plate 216 facing downward.

The loading unit 500 may be HCLU (Head Cup Loading Unloading).

The HCLU can serve to seat/hold the wafer 1. For example, prior to moving the wafer 1 arranged on a platen in a CMP process to the chamber 100 of the wafer cleaning device 10 according to an embodiment of the present disclosure, the HCLU may serve to seat/hold the wafer 1.

Alternatively, the HCLU may serve to seat/hold the wafer 1 before moving the wafer 1, which has been cleaned in the chamber 100, to a location for a subsequent process. Examples of the subsequent process include a cleaning process of the related art using a brush or the like.

For example, the HCLU may serve to place the wafer 1 thereon during the process of loading and unloading the wafer 1 between processes.

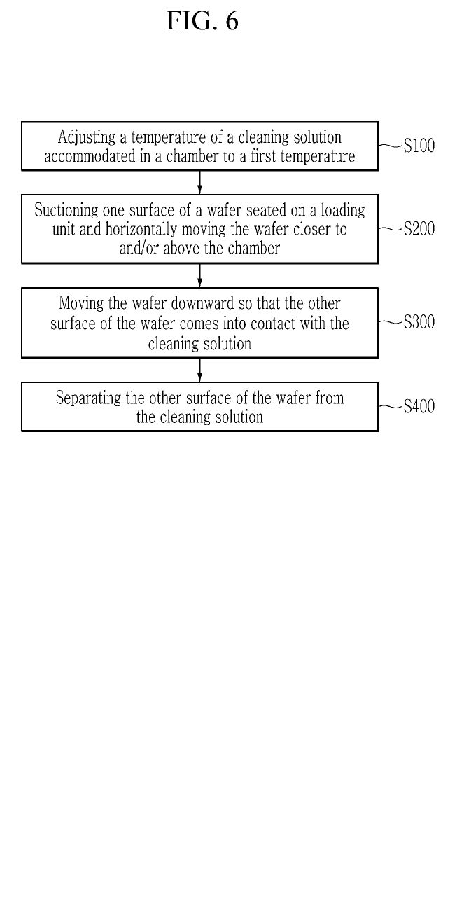

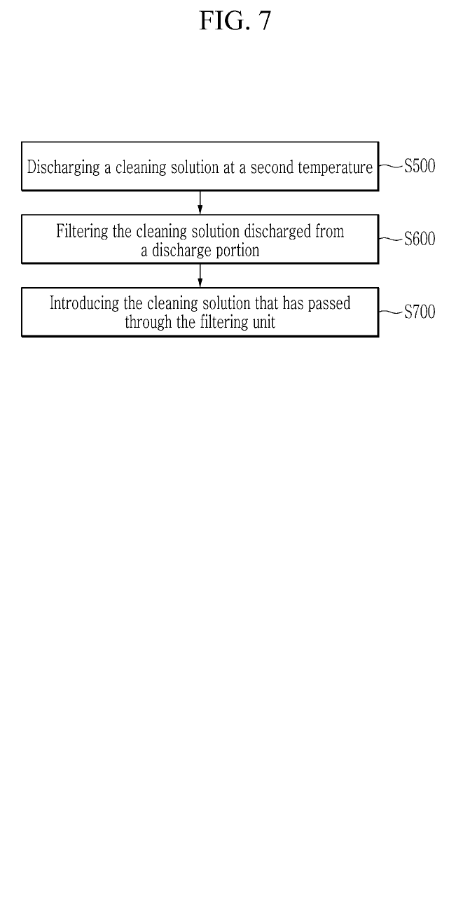

FIGS. 6 and 7 are diagrams illustrating a wafer cleaning method according to an embodiment.

Referring to FIG. 6, the wafer cleaning method according to an embodiment of the present disclosure may include a step (S100) of adjusting, by the temperature adjustment unit 300, a temperature of the cleaning solution 3 accommodated in the chamber 100 to a first temperature, a step (S200) of suctioning, by the head assembly 200, one surface of the wafer 1 seated on the loading unit 500 and horizontally moving the wafer 1 closer to and/or above the chamber 100, a step (S300) of moving, by the head assembly 200, the wafer 1 downward so that the other surface (an opposite surface to the one surface) of the wafer 1 comes into contact with the cleaning solution 3, thereby causing the particles 2 remaining on the other surface of the wafer 1 to adhere to the cleaning solution 3, and a step (S400) of separating, by the head assembly 200, the other surface of the wafer 1 from the cleaning solution 3.

The first temperature is a phase change temperature of the cleaning solution 3, and the cleaning solution 3 may be present in a rubbery state at the first temperature.

The step (S100) in which the temperature adjustment unit 300 adjusts the temperature of the cleaning solution 3 may include a step of controlling, by a control unit 320, a temperature of a heating portion 310 arranged in the chamber 100, and a step of transferring heat of the heating portion 310 to the cleaning solution 3.

The control unit 320 increases the temperature of the heating portion 310 arranged in the accommodation unit 110 of the chamber 100 in which the cleaning solution 3 is accommodated, thereby raising the temperature of the heating portion 310. After this, by transferring the heat of the heating portion 310 to the cleaning solution 3, the temperature of the cleaning solution 3 can be adjusted to the first temperature.

In some embodiments, the cleaning solution 3 accommodated in the accommodation unit 110 may be the cleaning solution 3 in a liquid state that has passed through the filtering unit 130. For example, the cleaning solution can be a reusing cleaning solution 3. The cleaning solution 3 in this state may be at the second temperature, and in the step of cleaning the wafer 1, the temperature of the cleaning solution 3 may be lowered to the first temperature.

When the heating portion 310 is a hose or pipe through which water or another fluid moves, the heat of the cleaning solution 3 can be transferred to the heating portion 310 by supplying cold water to the heating portion 310. For example, the heating portion 310 of the temperature adjustment unit 300 may be a temperature adjusting portion in certain embodiments such that the temperature adjusting portion can heat/cool the cleaning solution 3. The fluid moving through the temperature adjusting portion (the heating portion 310) is not limited to water and may include a refrigerant.

According to the above method, the temperature of the cleaning solution 3 can be lowered. This is only an example of a process of lowering the temperature of the cleaning solution 3, and the inventive concept is not limited thereto.

The step (S400) in which the wafer 1 is separated from the cleaning solution 3 may further include a step of increasing, by the temperature adjustment unit 300, the temperature of the cleaning solution 3 by a predetermined certain temperature, and a step of moving the support portion 230 of the head assembly 200 upward.

Here, the support portion 230 of the head assembly 200 moves upward to move the wafer 1 upward, and then the support portion 230 rotates, thereby enabling the wafer 1 to move above and to be seated on the loading unit 500.

By increasing the temperature of the cleaning solution 3 by a predetermined certain temperature as described above, the fluidity of the cleaning solution 3 can be increased. For example, the reason for increasing the temperature of the cleaning solution 3 by the predetermined temperature from the first temperature is to separate the wafer 1 from the cleaning solution 3 in a state where the fluidity of the cleaning solution 3 is higher than that at the first temperature.

For example, when the first temperature is 25°C to 30°C, the temperature of the cleaning solution 3 can be increased to about 40°C.

When the first temperature is 25°C to 30°C, the cleaning solution 3 is in a sticky rubbery state and has a high adhesive force. In this case, by bringing the wafer 1 into contact with the cleaning solution 3, the particles 2 attached to the wafer 1 can be attached to the cleaning solution 3.

After that, when the temperature of the cleaning solution 3 is adjusted to 40°C, the cleaning solution 3 may have higher fluidity compared to when it is at 25°C to 30°C. However, even in this state, since the cleaning solution 3 has an adhesive force, the particles 2 can remain adhered to the cleaning solution 3. As the fluidity of the cleaning solution 3 increases, the adhesive force may be slightly reduced, making it easier to separate the wafer 1 from the cleaning solution 3.

In some embodiments, the method may further include a step of, after bringing the wafer 1 into contact with the cleaning solution 3 at the first temperature (25°C to 30°C), increasing the temperature of the cleaning solution 3 to about the second temperature (60°C) or higher before adjusting the temperature of the cleaning solution 3 to 40°C. After that, the temperature of the cleaning solution 3 is adjusted to 40°C.

The reason for increasing the temperature of the cleaning solution 3 to the second temperature (melting point) or higher is that, when the temperature of the cleaning solution 3 is increased to the second temperature or higher, the cleaning solution 3 becomes a liquid state, causing the particles 2 adhered to the surface of the cleaning solution 3 to sink below a top surface of the cleaning solution 3, thereby allowing the particles to mix better in the cleaning solution 3.

When the temperature of the cleaning solution 3 is again lowered to about 40°C, the fluidity of the cleaning solution 3 becomes lower compared to when it is at the second temperature, and the particles 2 mixed in the cleaning solution 3 remain in the cleaning solution 3.

When the above step is further included, a possibility that particles 2 adhered to the surface of the cleaning solution 3 by the adhesive force of the cleaning solution 3 move together with the wafer 1 while attached to the wafer 1 and remain on the wafer 1 can be further reduced.

After the wafer 1 is separated from the cleaning solution 3, the temperature adjustment unit 300 may adjust the temperature of the cleaning solution 3 to the second temperature. The second temperature is a temperature equal to or higher than the melting point (Tm) of the cleaning solution 3, and the cleaning solution 3 can be present in a liquid state at the second temperature.

In some embodiments, as the rotating unit 160 arranged in an aqueous solution in the chamber 100 rotates, a vortex can be generated in the cleaning solution 3 accommodated in the chamber 100.

The cleaning solution 3 at the second temperature or higher is in a liquid state and can be rotated by the vortex generated by the rotating unit 160. This is to ensure that the particles 2 in the cleaning solution 3 are evenly distributed throughout the cleaning solution 3.

Referring to FIG. 7, the wafer cleaning method according to an embodiment of the present disclosure includes, after the step (S400) of separating, by the head assembly 200, the other surface of the wafer 1 from the cleaning solution 3, a step (S500) of discharging, by the discharge portion 120, the cleaning solution 3 at a second temperature, a step (S600) of filtering, by the filtering unit 130, the cleaning solution 3 discharged from the discharge portion 120, and a step (S700) of introducing, by the inlet portion 140, the cleaning solution 3 that has passed through the filtering unit 130 into the chamber 100.

The cleaning solution 3 discharged through the discharge portion 120 is in a liquid state and has high fluidity, making it easy to move from the chamber 100 and to discharge through the discharge portion 120.

The filtering step is a process of removing the particles 2 in the cleaning solution 3, and the cleaning solution 3 that has passed through the filtering unit 130 can be reused. The wafer cleaning method according to the present disclosure is advantageous in terms of cost and environmental efficiency, as the cleaning solution 3 can be used semi-permanently or at least multiple times.

Even though different figures illustrate variations of exemplary embodiments and different embodiments disclose different features from each other, these figures and embodiments are not necessarily intended to be mutually exclusive from each other. Rather, features depicted in different figures and/or described above in different embodiments can be combined with other features from other figures/embodiments to result in additional variations of embodiments, when taking the figures and related descriptions of embodiments as a whole into consideration. For example, components and/or features of different embodiments described above can be combined with components and/or features of other embodiments interchangeably or additionally to form additional embodiments unless the context clearly indicates otherwise, and the present disclosure includes the additional embodiments.

While the present disclosure has been described in connection with what is presently considered to be practical embodiments, it is to be understood that the present disclosure is not limited to the disclosed embodiments. On the contrary, it is intended to cover various modifications and equivalent arrangements included within the spirit and scope of the appended claims.

What is claimed is:

1. A wafer cleaning device comprising:
a chamber configured to accommodate a cleaning solution including a thermo-responsive polymer, the chamber having a structure with open top;
a head assembly configured to suction one surface of a wafer and move the wafer so that the other surface of the wafer comes into contact with the cleaning solution; and
a temperature adjustment unit arranged in the chamber and configured to adjust a temperature of the cleaning solution.

2. The wafer cleaning device of claim 1, wherein:
the temperature adjustment unit comprises
a heating portion configured to transmit heat to the cleaning solution; and
a temperature controller configured to control a temperature of the heating portion.

3. The wafer cleaning device of claim 2, wherein:
the heating portion is arranged in an accommodation unit of the chamber in which the cleaning solution is accommodated.

4. The wafer cleaning device of claim 1, wherein:
the head assembly comprises:
a suction head configured to suction the wafer;
a connection portion connected to the suction head on one side of the connection portion to support the suction head;
a support portion horizontally spaced apart from the suction head and connected to the other side of the connection portion to support the connection portion; and
a driving unit configured to move the support portion.

5. The wafer cleaning device of claim 4, wherein:
the support portion is rotatable about a vertical axis together with the suction head.

6. The wafer cleaning device of claim 4, wherein:
the support portion is movable vertically along with the suction head.

7. The wafer cleaning device of claim 1, further comprising
a temperature sensor configured to detect the temperature of the cleaning solution.

8. The wafer cleaning device of claim 1, further comprising
a discharge portion provided to the chamber and configured to discharge the cleaning solution from the chamber;
a solution filter configured to receive and filter the cleaning solution discharged from the discharge portion; and
an inlet portion provided to the chamber and configured to introduce the cleaning solution that has passed through the solution filter into the chamber.

9. The wafer cleaning device of claim 8, further comprising
a pump configured to apply pressure to the cleaning solution so that the cleaning solution having passed through the solution filter flows into the chamber.

10. The wafer cleaning device of claim 1, wherein:
the chamber further comprises a stirrer configured to generate a vortex in the cleaning solution accommodated in the chamber.

11. The wafer cleaning device of claim 1,
wherein the cleaning solution comprises at least one of thermoplastic urethane (TPU) and poly(N-isopropylacrylamide) (PNIPAM).

12. A wafer cleaning device comprising:
a chamber configured to accommodate a cleaning solution including a thermo-responsive polymer, the chamber having a cylindrical structure with open top;
a loading unit configured such that a wafer is seated on the loading unit;
a suction head configured to suction one surface of the wafer;
a connection portion connected to the suction head on one side of the connection portion to support the suction head;
a support portion connected to the other side of the connection portion to support the connection portion, the support portion rotatable about a vertical axis along with the suction head and movable along the vertical axis; and
a temperature adjustment unit configured to adjust a temperature of the cleaning solution.

13. The wafer cleaning device of claim 12, wherein:
a diameter of the open top of the chamber is equal to or greater than a diameter of a suction plate of the suction head.

14. A wafer cleaning method comprising:
adjusting a temperature of a cleaning solution accommodated in a chamber to a first temperature;
suctioning one surface of a wafer seated on a loading unit and moving the wafer above the chamber;
moving the wafer downward so that the other surface of the wafer comes into contact with the cleaning solution; and
separating the other surface of the wafer from the cleaning solution,
wherein the first temperature is a phase change temperature of the cleaning solution, and the cleaning solution is present in a rubbery state at the first temperature.

15. The wafer cleaning method of claim 14, wherein:
the separating of the wafer from the cleaning solution further comprises:
increasing a temperature of the cleaning solution by a certain temperature; and
moving a support portion of a head assembly upward, and
wherein fluidity of the cleaning solution increases as the temperature of the cleaning solution increases by the certain temperature.

16. The wafer cleaning method of claim 15, wherein:
after the support portion of the head assembly moves upward, the support portion of the head assembly rotates to rest the wafer on the loading unit.

17. The wafer cleaning method of claim 14, wherein:
after the wafer is separated from the cleaning solution, the cleaning solution is adjusted to a second temperature, and
the second temperature is a temperature equal to or higher than a melting point of the cleaning solution, and the cleaning solution is present in a liquid state at the second temperature.

18. The wafer cleaning method of claim 17, further comprising:
discharging the cleaning solution at the second temperature;
filtering the cleaning solution discharged through a discharge portion; and
introducing the cleaning solution that has passed through a filter into the chamber.

19. The wafer cleaning method of claim 14, wherein:
the adjusting of the temperature of the cleaning solution comprises:
controlling a temperature of a heating portion arranged in the chamber; and
transferring heat of the heating portion to the cleaning solution.

20. The wafer cleaning method of claim 14, further comprising:
generating a vortex in the cleaning solution accommodated in the chamber with a stirrer.
